(19) United States
(12) Patent Application Publication
(10) Pub. No.: US 2026/0290438 A1
(43) Pub. Date: Sep. 24, 2026

(54) MEMORY DEVICE, METHOD OF PROGRAMMING THE SAME, AND MEMORY SYSTEM INCLUDING THE SAME

(71) Applicant: Samsung Electronics Co., Ltd., Suwon-si (KR)

(72) Inventors: Suhyun BANG, Suwon-si (KR); Jongmin BAEK, Suwon-si (KR); Seulji SONG, Suwon-si (KR)

(73) Assignee: Samsung Electronics Co., Ltd., Suwon-si (KR)

(21) Appl. No.: 19/456,286

(22) Filed: Jan. 22, 2026

(30) Foreign Application Priority Data
Mar. 18, 2025 (KR) 10-2025-0034378

(51) Int. Cl. G11C 11/4096; G11C 11/4074; G11C 11/408

(52) U.S. Cl. CPC G11C 11/4096; G11C 11/4074; G11C 11/4085

(57) ABSTRACT

A memory device may include a cell region and a peripheral circuit region. The cell region may include memory cells including a selector. The peripheral circuit region may include a current monitoring circuit and a voltage controller. In programming operation for a selected memory cell, the voltage controller may input a first word line voltage to a selected word line, the current monitoring circuit may compare a current of the selected word line with a reference current, and the voltage controller may input a second word line voltage higher than the first word line voltage to the selected word line when the current of the selected word line is greater than the reference current and may input a first bit line voltage or a second bit line voltage to a selected bit line when the current of the selected word line is less than the reference current.

### CROSS-REFERENCE TO RELATED APPLICATION(S)

This application claims benefit of priority to Korean Patent Application No. 10-2025-0034378, filed on Mar. 18, 2025 in the Korean Intellectual Property Office, the disclosure of which is incorporated herein by reference in its entirety.

### BACKGROUND

The present disclosure relates to a memory device, a method of programming the same, and a memory system including the same.

Research on Selector-Only Memory (SOM) has been actively conducted as a Compute Express Link (CXL) memory solution. Devices such as transistors, diodes, tunnel barrier devices, or ovonic threshold switches (OTS) are proposed as selectors. Due to the bidirectional operation characteristics of the selector, memory cells including the selector may have threshold voltages of two voltage ranges. In a selection-based memory, when executing a programming operation for a selected memory cell, a problem may occur in which a programming operation for the selected memory cell may not be normally executed when a non-selected memory cell with a relatively low threshold voltage range is unintentionally turned on only by the word line voltage or bit line voltage.

### SUMMARY

An aspect of the present disclosure is to provide a memory device having improved performance by performing a pre-programming operation configured to monitor a current by inputting a voltage to a selected word line or a selected bit line and to find an appropriate voltage to be input to the selected word line or the selected bit line, and compensating for a word line voltage input to the selected word line and a bit line voltage input to the selected bit line to limit and/or prevent unintentional turning-on of a non-selected memory cell and increasing a success rate of a programming operation for the selected memory cells.

A memory device according to an example embodiment of the present disclosure may include a cell region including a plurality of memory cells in regions where a plurality of word lines and a plurality of bit lines intersect each other, the plurality of memory cells each respectively including a selector such that the plurality of memory cells respectively include a plurality of selectors; and a peripheral circuit region including a current monitoring circuit and a voltage controller, the current monitoring circuit being configured to monitor a current flowing through the plurality of word lines, and the voltage controller being configured to input a voltage to each of the plurality of word lines and the plurality of bit lines. In a programming operation for a selected memory cell connected to a selected word line among the plurality of word lines and a selected bit line among the plurality of bit lines, the voltage controller may be configured to input a first word line voltage to the selected word line, the current monitoring circuit may be configured to compare a current of the selected word line with a reference current, the voltage controller may be configured to input a second word line voltage to the selected word line when the current of the selected word line is greater than the reference current, and the voltage controller may be configured to input a first bit line voltage or a second bit line voltage to the selected bit line when the current of the selected word line is less than the reference current. The second word line voltage is higher than the first word line voltage. The second bit line voltage may be higher than the first word line voltage.

A method of programing a memory device according to an example embodiment may be provided. The memory device may include a plurality of memory cells disposed in regions in which a plurality of word lines and a plurality of bit lines may intersect each other, and the plurality of memory cells respectively each may include a selector. The method may include inputting a first word line voltage to a selected word line in a programming operation for a selected memory cell connected to the selected word line, the selected word line being among the plurality of word lines; comparing a current of the selected word line with a reference current; inputting a second word line voltage to the selected word line when a current of the selected word line is greater than the reference current, the second word line voltage being higher than the first word line voltage; and inputting a first bit line voltage or a second bit line voltage to a selected bit line connected to the selected memory cell when the current of the selected word line is less than the reference current. The second bit line voltage may be higher than the first bit line voltage. The selected bit line may be among the plurality of bit lines.

A memory system according to an example embodiment of the present disclosure may include a host using a Compute Express Link (CXL) interface; and a memory device including a plurality of memory cells connected to the host. The plurality of memory cells may be disposed in regions in which a plurality of word lines and a plurality of bit lines may intersect each other. The plurality of memory cells respectively each may include a selector. The memory device may include a voltage controller configured to input voltages to the plurality of word lines and the plurality of bit lines. In a programming operation for a selected memory cell connected to a selected word line among the plurality of word lines and a selected bit line among the plurality of bit lines, the voltage controller may be configured to input a word line voltage to the selected word line. The voltage controller may be configured to provide a compensated word line voltage by compensating for the word line voltage that input to the selected word line until a current of the selected word line is lower than a reference current during a first time and the voltage controller may be configured to compensate for a bit line voltage input to the selected bit line based on the compensated word line voltage during a second time after the first time.

According to an example embodiment of the present disclosure, a current monitoring circuit may monitor whether at least one non-selected memory cell connected to a selected word line is turned on, and a voltage controller may compensate a voltage input to a selected bit line and a selected word line, so that the non-selected memory cell having a relatively low threshold voltage may not be turned on, and the selected memory cell having a relatively high threshold voltage may be turned on, thereby successfully executing a programming operation for the selected memory cell, and improving the performance of the memory device.

Advantages and effects of the present application are not limited to the foregoing content and may be more easily understood in the process of describing a example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a view simply illustrating a memory system according to an example embodiment of the present disclosure;

FIG. 2 is a block diagram simply illustrating a memory device according to an example embodiment of the present disclosure;

FIG. 3 is a block diagram simply illustrating a memory device according to an example embodiment of the present disclosure;

FIG. 4 is a view simply illustrating a portion of a memory cell according to an example embodiment of the present disclosure;

FIG. 5 is a view illustrating threshold voltage distribution of memory cells in a memory device according to an example embodiment of the present disclosure;

FIG. 6A and FIG. 6B are views provided to illustrate a programming operation of a memory device according to an example embodiment of the present disclosure;

FIG. 7A to FIG. 7C are views provided to illustrate a programming operation of a memory device according to an example embodiment of the present disclosure;

FIG. 8, FIG. 9A and FIG. 9B are views provided to illustrate a programming operation of a memory device according to an example embodiment of the present disclosure;

FIG. 10A and FIG. 10B are views provided to explain a programming operation of a memory device according to an example embodiment of the present disclosure; and

FIGS. 11 and 12 are flowcharts provided to illustrate a programming operation of a memory device according to an example embodiment of the present disclosure.

### DETAILED DESCRIPTION

Hereinafter, example embodiments of the present disclosure will be described with reference to the accompanying drawings.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

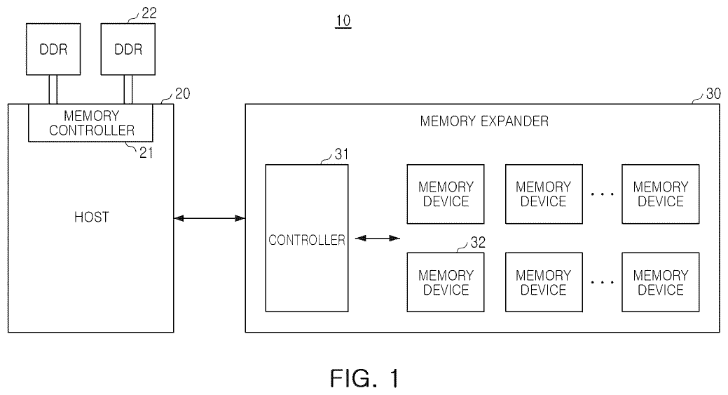

FIG. 1 is a view simply illustrating a memory system according to an example embodiment of the present disclosure.

A memory system 10 illustrated in FIG. 1 may be a Compute Express Link (CXL) memory system. For example, a memory expander 30 included in the memory system 10 may be connected to a central processing unit (CPU), a graphic processing unit (GPU), an AI accelerator, a storage device, and the like, of a host device 20 based on a Peripheral Component Interconnect Express (PCIe) interface. The memory expander 30 may support a cache-coherent interconnect.

The memory system 10 may include the host device 20. A memory controller 21 of the host device 20 may be directly connected to a host or a central processing unit and may manage data exchange with at least one Double Data Rate (DDR) memory 22. The host device 20 may include a home agent (not shown), which may manage memory access within the host device 20. The home agent may communicate with the memory expander 30 via protocols such as CXL.IO and CXL.memory.

The memory system 10 may include the memory expander 30. The memory expander 30 may include a controller 31 and a plurality of memory devices 32. The controller 31 may control the plurality of memory devices 32. For example, the controller 31 may control the plurality of memory devices 32 according to the request of a processor supporting various applications such as a server application, a Personal Computer (PC) application, and a mobile application. The controller 31 may communicate with the host device 20 including the processor using the CXL protocol, and may control the plurality of memory devices 32 according to the request of the processor. For example, the controller 31 may communicate with the host device 20 on the PCIe bus based on the CXL. IO protocol and may control the memory device 32 based on the CXL. memory protocol.

The controller 31 may be implemented with a plurality of memory devices 32 in one package. Alternatively, the controllers 31 may communicate with each other on the same bus connected to the host device 20 and may be implemented in different packages. The controller 31 may transmit commands and/or addresses to the plurality of memory devices 32 to control the plurality of memory devices 32. In addition, the controller 31 may transmit data to the plurality of memory devices 32 or receive data from the plurality of memory devices 32.

The plurality of memory devices 32 may include various non-volatile memories such as a NAND flash memory, an Electrically Erasable Read-Only Memory (EEPROM), a Ferroelectric RAM (FeRAM), a Magnetoresistive RAM (MRAM), a Phase Change Memory (PCM), and a Resistive Random Access Memory (ReRAM). Alternatively, the plurality of memory devices 32 may also include various DRAM devices such as a Double Data Rate Synchronous Dynamic Random Access Memory (DDR SDRAM), a Low Power Double Data Rate (LPDDR) SDRAM, and a Graphics Double Data Rate Synchronous Graphics Random Access Memory (GDDR SGRAM).

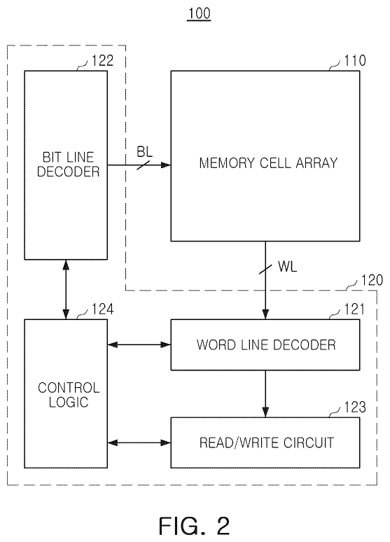

FIG. 2 is a block diagram simply illustrating a memory device according to an example embodiment of the present disclosure.

A memory device 100 according to an example embodiment of the present disclosure may include a cell region 110 and a peripheral circuit region 120. The cell region 110 may include a plurality of memory cells, which may be arranged in a memory cell array. The peripheral circuit region 120 may include decoder circuits 121 and 122, one or more read/write circuits 123, and a control logic 124.

The decoder circuits 121 and 122 may include a word line decoder 121 connected to the plurality of memory cells through word lines WL and a bit line decoder 122 connected to the plurality of memory cells through bit lines BL. The operations of the word line decoder 121, the bit line decoder 122, and the read/write circuit 123 may be controlled by the control logic 124. In an example embodiment, the read/write circuit 123 may include a program circuit that writes data to a selected memory cell specified by the word line decoder 121 and the bit line decoder 122, and a readout circuit that reads data from the selected memory cell.

The control logic 124 may determine a selected memory cell among the memory cells included in the cell region 110, through the word line decoder 121 and the bit line decoder 122. The control logic 124 may execute a programming operation, a read operation, a refresh operation, and the like, for the selected memory cell, by inputting a desired and/or alternatively predetermined bias to each of a selected word line and a selected bit line connected to the selected memory cell.

For example, in the memory device 100, the word line decoder 121 and the bit line decoder 122 may be disposed below the cell region 110. In other words, the cell region 110 may be disposed above the word line decoder 121 and the bit line decoder 122. By utilizing the structure as described above, an interconnection design connecting the word lines WL and the word line decoder 121, and the bit lines BL and the bit line decoder 122 may be simplified. According to example embodiments, the read/write circuit 123 may also be disposed below the cell region 110 together with the word line decoder 121 and the bit line decoder 122.

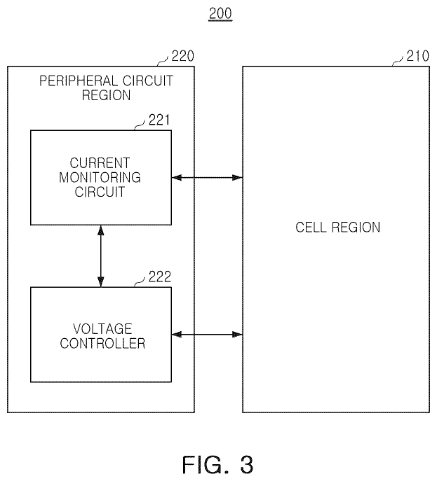

FIG. 3 is a block diagram simply illustrating a memory device according to an example embodiment of the present disclosure.

Referring to FIG. 3, a memory device 200 according to an example embodiment of the present disclosure may include a cell region 210 and a peripheral circuit region 220. Memory cells, and word lines and bit lines connected to the memory cells may be formed in the cell region 210. The memory cells in the cell region 210 may be arranged as a memory cell array. The peripheral circuit region 220 may include various circuits necessary for an operation of the memory device 200.

The cell region 210 may include a cell array including a plurality of memory cells. In an example embodiment, the cell array may have a cross-point structure in which word lines and bit lines are arranged in a grid pattern. The plurality of memory cells may be disposed in regions in which the word lines and bit lines intersect each other, and may include a selector. In an example embodiment, each of the plurality of memory cells may be implemented with only one selector without a separate information storage element.

In an example embodiment, the selector may be an Ovonic Threshold Switch (OTS) selector including a chalcogenide compound. The OTS selector is a two-terminal symmetric voltage-sensitive switching element, and may be switched from a high resistance state to a conducting state and may then maintain a current, and may return to a high resistance state when a current value drops downwardly. The OTS selector may be formed of a chalcogenide, which is a compound including at least one Group 16 (chalcogen) element and one or more electropositive elements.

The selector may have a first threshold voltage and a second threshold voltage, where the second threshold voltage may be lower than the first threshold voltage. The first threshold voltage may be a minimum voltage required for a memory cell to first switch from a turn-off state to a turn-on state. When a voltage higher than the first threshold voltage is input to the selector, the resistance of the selector may rapidly decrease and a current may begin to flow. When a voltage input to the memory cell in the turn-on state is reduced, the memory cell may switch from the turn-on state to the turn-off state under the condition that a voltage decreases below the second threshold voltage, lower than the first threshold voltage. That is, a threshold voltage of the memory cell may decrease from the first threshold voltage to the second threshold voltage.

The peripheral circuit region 220 of the memory device 200 according to an example embodiment of the present disclosure may include a current monitoring circuit 221 and a voltage controller 222. For example, the current monitoring circuit 221 and the voltage controller 222 may be included in the control logic of the peripheral circuit region 220. Alternatively, the current monitoring circuit 221 and the voltage controller 222 may not be included in the control logic of the peripheral circuit region and may exist separately.

In a programming operation for a selected memory cell among a plurality of memory cells, the current monitoring circuit 221 may compare a current of a selected word line connected to the selected memory cell, among the plurality of memory cells, with a reference current. The reference current may be determined based on a minimum current flowing to the selected memory cell when the selected memory cell is in a turn-on state. By comparing the current of the selected word line with the reference current, the current monitoring circuit 221 may determine whether at least one non-selected memory cell connected to the selected word line is in the turn-on state.

A programming operation for the selected memory cell connected to a selected word line among a plurality of word lines may be performed by inputting a first word line voltage to the selected word line and inputting a first bit line voltage to the selected bit line connected to the selected memory cell. The first word line voltage and the first bit line voltage may be voltages input to the selected word line and the selected bit line, respectively, by default settings in the programming operation for the selected memory cell.

In an example embodiment, the first word line voltage and the first bit line voltage may have different polarities, and the first word line voltage may be a negative voltage and the first bit line voltage may be a positive voltage. The program voltage may be determined by the sum of the absolute value of the first word line voltage and the absolute value of the first bit line voltage. For example, in the programming operation for a selected memory cell, the first word line voltage may be first input to the selected word line, and then the first bit line voltage may be input to the selected bit line.

However, at least one non-selected memory cell may be connected to the selected word line in addition to the selected memory cell. Depending on whether the non-selected memory cell is programmed, the non-selected memory cell may be unintentionally turned on by the first word line voltage input to the selected word line. For example, when the non-selected memory cell is programmed and has a second threshold voltage, the non-selected memory cell may be turned on as the first word line voltage is input to the selected word line. As the non-selected memory cell is unintentionally turned on, a current flowing to the selected memory cell may decrease, and the programming operation for the selected memory cell may not be performed normally.

In an example embodiment of the present disclosure, the current of the selected word line may be detected in a state in which the first word line voltage is input to the selected word line, thus determining whether the non-selected memory cell connected to the selected word line is turned on. In addition, by changing the voltage input to each of the selected word line and the selected bit line based on whether the non-selected memory cell is turned on, unintentional turn-on of the non-selected memory cell may be limited and/or prevented, and a success rate of the programming operation for the selected memory cell may be increased.

When the non-selected memory cell connected to the selected word line is programmed, a threshold voltage of the non-selected memory cell may be a relatively low second threshold voltage. The voltage controller 222 may input a first word line voltage to the selected word line to program the selected memory cell, and the non-selected memory cell may be unintentionally turned on by the first word line voltage input to the selected word line. When the non-selected memory cell is unintentionally turned on, the current of the selected word line may be greater than the reference current. In this manner, when the programmed non-selected memory cell is unintentionally turned on, the current monitoring circuit 221 may determine that the current of the selected word line is greater than the reference current.

In an example embodiment of the present disclosure, when the current monitoring circuit 221 determines that the current of the selected word line is greater than the reference current, the voltage controller 222 may input a second word line voltage higher than the first word line voltage to the selected word line. For example, the first word line voltage and the second word line voltage may be negative voltages and an absolute value of the second word line voltage may be less than an absolute value of the first word line voltage. By increasing the voltage input to the selected word line by the voltage controller 222 to the second word line voltage, the non-selected memory cell connected to the selected word line may be limited and/or prevented from being unintentionally turned on due to the voltage input to the selected word line.

When the non-selected memory cell connected to the selected word line is not programmed, a threshold voltage of the non-selected memory cell may be a relatively high first threshold voltage. The voltage controller 222 may input the first word line voltage to the selected word line to program the selected memory cell, and the non-selected memory cell may not be turned on by the first word line voltage input to the selected word line, so that the current monitoring circuit 221 may determine that the current of the selected word line is less than the reference current.

In an example embodiment, while the voltage controller 222 increases the voltage input to the selected word line from the first word line voltage, the current monitoring circuit 221 may compare the current flowing in the selected word line with the reference current. For example, when the current monitoring circuit 221 determines that the current flowing in the selected word line is greater than the reference current even though the voltage controller 222 inputs a voltage higher than the first word line voltage to the selected word line, the voltage controller 222 may further increase a voltage of the selected word line.

For example, the voltage controller 222 may gradually increase the voltage of the selected word line until the current flowing in the selected word line is less than the reference current. In a state in which the voltage controller 222 inputs a voltage higher than the first word line voltage to the selected word line, when the current monitoring circuit 221 determines that the current flowing to the selected word line is less than the reference current, the second word line voltage to be input to the selected word line to execute the programming operation may be determined.

However, in a state in which the voltage controller 222 inputs a second word line voltage higher than the first word line voltage to the selected word line, when the voltage controller 222 inputs the first bit line voltage to the selected bit line, a difference between the second word line voltage and the first bit line voltage may not reach the program voltage, so that the selected memory cell may not be programmed. Therefore, in the present disclosure, when the second word line voltage is input to the selected word line, the voltage controller 222 may input a second bit line voltage higher than the first bit line voltage to the selected bit line. By inputting the second word line voltage to the selected word line and the second bit line voltage to the selected bit line, the selected memory cell may be normally programmed. For example, the first bit line voltage and the second bit line voltage may be positive voltages.

In an example embodiment of the present disclosure, when the current of the selected word line is determined to be less than the reference current by the current monitoring circuit 221, the voltage controller 222 may input the first bit line voltage or the second bit line voltage higher than the first bit line voltage to the selected bit line. For example, when the first word line voltage is input to the selected word line, the voltage controller 222 may input the first bit line voltage to the selected bit line. When the second word line voltage is input to the selected word line, the voltage controller 222 may input the second bit line voltage to the selected bit line. For example, a difference between the first word line voltage and the second word line voltage may be the same as a difference between the first bit line voltage and the second bit line voltage.

The memory device 200 according to an example embodiment of the present disclosure may compensate for the voltage input to the selected word line and the voltage input to the selected bit line using the current monitoring circuit 221 and the voltage controller 222, so that at least one non-selected memory cell connected to the selected word line and having a second threshold voltage may be limited and/or prevented from being turned on, and the success rate of the programming operation for the selected memory cell may be increased, thereby improving the performance of the memory device 200.

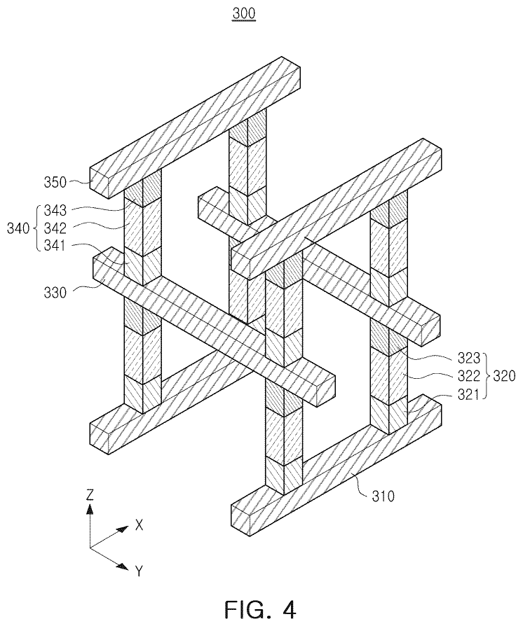

FIG. 4 is a view simply illustrating a portion of a memory cell according to an example embodiment of the present disclosure.

Referring to FIG. 4, a cell array 300 may include bit lines 330 extending in a first direction (Y-axis direction) and word lines 310 and 350 extending in a second direction (X-axis direction). The first direction and the second direction are directions intersecting each other, and may be, for example, perpendicular to each other.

The cell array 300 may include lower word lines 310 disposed below the bit lines 330 and upper word lines 350 disposed above the bit lines 330. Lower memory cells 320 may be disposed between the bit lines 330 and the lower word lines 310, and upper memory cells 340 may be disposed between the bit lines 330 and the upper word lines 350.

Each of the lower memory cells 320 may include a first electrode layer 321, a selector layer 322, and a second electrode layer 323, which are sequentially stacked. The selector layer 322 may include a material whose resistance changes depending on the magnitude of voltages applied to two ends thereof, and may include, for example, an Ovonic Threshold Switching (OTS) material. The OTS material may include a chalcogenide switching material. In an example embodiment, the selector layer 322 may include Si, Te, As, Ge, In, or combinations of these elements, or may further include nitrogen. The constituent materials of the selector layer 322 are not limited to those examples above, and may include various material layers that may perform the function of selecting elements.

The upper memory cells 340 and the upper word lines 350 may be disposed above the bit lines 330. The upper memory cells 340 may have the same structure as the lower memory cells 320. For example, each of the upper memory cells 340 may include a first electrode layer 341, a selector layer 342 and a second electrode layer 343, which are sequentially stacked.

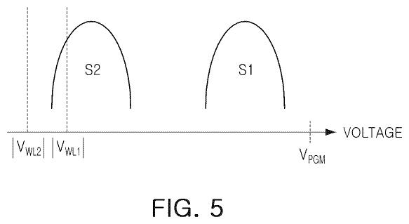

FIG. 5 is a view illustrating threshold voltage distribution of memory cells in a memory device according to an example embodiment of the present disclosure.

Referring to FIG. 5, memory cells have a first state S1 or a second state S2. For example, the memory cells in the first state S1 may have a threshold voltage of a first voltage range, and memory cells in the second state S2 may have a threshold voltage of a second voltage range, where the second voltage may be less than the first voltage range. For example, the threshold voltages of each of the memory cells may be determined by the magnitude of the resistance of the selector.

In an example embodiment, in each of the memory cells in the first state S1, the selector may have a relatively large resistance, and in each of the memory cells in the second state S2, the selector may have a relatively small resistance. For example, the first state S1 is a state in which a chalcogenide series material included in the selector has an amorphous phase, and may be defined as a reset state. In addition, the second state S2 is a state in which a chalcogenide series material included in the memory element has a crystalline phase, and may be defined as a set state.

The programming operation of the memory device may be executed by inputting a first word line voltage V_{WL1} to the selected word line connected to the selected memory cell, and inputting a first bit line voltage to the selected bit line connected to the selected memory cell. For example, referring to FIG. 5, the memory cells of the first state S1 may be programmed and then switched to the memory cells of the second state S2. A threshold voltage of the programmed memory cell may be reduced compared to the threshold voltage of the memory cell before the program, and the selected memory cell may be an unprogrammed memory cell, that is, a memory cell of the first state S1.

A voltage controller of the memory device may first input the first word line voltage V_{WL1} to the selected word line to execute a pre-programming operation. An absolute value of the first word line voltage V_{WL1} may be less than a minimum voltage of the first voltage range. Accordingly, among the memory cells connected to the selected word line, memory cells having the first state S1 may not be turned on even if the first word line voltage V_{WL1} is input to the selected word line.

On the other hand, as illustrated in FIG. 5, the first word line voltage V_{WL1} may be higher than a minimum voltage of the second voltage range. Accordingly, when the first word line voltage V_{WL1} is input to the selected word line, at least one non-selected memory cell having the second state S2 and a threshold voltage less than the first word line voltage V_{WL1}, among the memory cells connected to the selected word line, may be unintentionally turned on. In this manner, among the non-selected memory cells of the second state S2 connected to the selected word line, as the at least one non-selected memory cell having the threshold voltage lower than the first word line voltage V_{WL1} is turned on, a voltage of the selected word line decreases and the programming operation for the selected memory cell may fail.

In an example embodiment of the present disclosure, to limit and/or prevent the non-selected memory cell of the second state S2 from being turned on, and improve the reliability of the memory device, the voltage controller may input a second word line voltage V_{WL2} higher than the first word line voltage V_{WL1} to the selected word line. For example, the first word line voltage V_{WL1} and the second word line voltage V_{WL2} may be negative voltages, and an absolute value of the second word line voltage V_{WL2} may be lower than the first word line voltage V_{WL1}. Referring to FIG. 5, the absolute value of the second word line voltage V_{WL2} may be less than the second voltage range. Accordingly, the memory cell in the second state S2 may not be turned on by the second word line voltage V_{WL2} input to the selected word line.

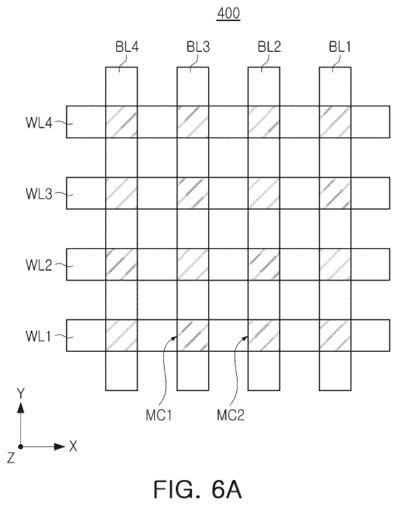

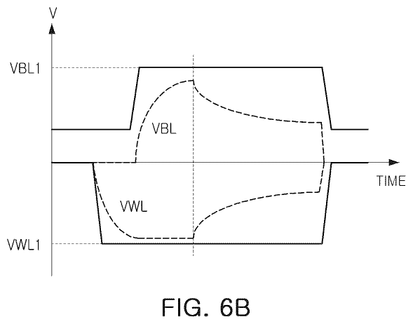

FIGS. 6A and 6B are views provided to illustrate a programming operation of the memory device according to an example embodiment of the present disclosure.

First, referring to FIG. 6A, a cell array 400 may include first to fourth word lines WL1 to WL4, first to fourth bit lines BL1 to BL4, and a plurality of memory cells. The plurality of memory cells may be disposed in a region in which the first to fourth word lines WL1 to WL4 and the first to fourth bit lines BL1 to BL4 intersect each other, respectively. In this case, the number of each component is only an example shown for convenience of explanation, and is not limited to the number.

The first to fourth word lines WL1 to WL4 may extend in parallel in the second direction (X-axis direction). The first to fourth word lines WL1 to WL4 may be spaced apart from each other in the first direction (Y-axis direction). The first to fourth word lines WL1 to WL4 may be formed in parallel at the same height level. The first to fourth word lines WL1 to WL4 may include a conductor. For example, the first to fourth word lines WL1 to WL4 may include a metal such as tungsten (W), platinum (Pt), palladium (Pd), rhodium (Rh), ruthenium (Ru), iridium (Ir), copper (Cu), aluminum (Al), titanium (Ti), and tantalum (Ta), but the present disclosure is not limited thereto.

The first to fourth bit lines BL1 to BL4 may be formed on the first to fourth word lines WL1 to WL4. The first to fourth bit lines BL1 to BL4 may extend parallel in a first direction. The first to fourth bit lines BL1 to BL4 may be spaced apart from each other in the second direction. Accordingly, the first to fourth word lines WL1 to WL4 and the first to fourth bit lines BL1 to BL4 may form a mesh structure in plan view. The first to fourth bit lines BL1 to BL4 may be formed in positions orthogonal to the first to fourth word lines WL1 to WL4. In another example embodiment, the first to fourth bit lines BL1 to BL4 may be formed at an acute angle with the first to fourth word lines WL1 to WL4. The first to fourth bit lines BL1 to BL4 may include a conductor. For example, the first to fourth word lines WL1 to WL4 may include a metal such as tungsten (W), platinum (Pt), palladium (Pd), rhodium (Rh), ruthenium (Ru), iridium (Ir), copper (Cu), aluminum (Al), titanium (Ti), and tantalum (Ta), but the present disclosure is not limited thereto.

A plurality of memory cells may be connected to at least one of the first to fourth word lines WL1 to WL4 and to at least one of the first to fourth bit lines BL1 to BL4. For example, a lower surface of a first memory cell MC1 may be connected to a first word line WL1, and an upper surface of the first memory cell MC1 may be connected to a third bit line BL3. A lower surface of the second memory cell MC2 may be connected to the first word line WL1, and an upper surface of the second memory cell MC2 may be connected to a second bit line BL2.

In an example embodiment illustrated in FIG. 6A, the first memory cell MC1 may be a selected memory cell. Accordingly, the first word line WL1 connected to the first memory cell MC1 may be a selected word line, and the third bit line BL3 connected to the first memory cell MC1 may be a selected bit line. The first memory cell MC1 is an unprogrammed memory cell and may have a threshold voltage in the first voltage range as described above with reference to FIG. 5.

The second memory cell MC2 may be a non-selected memory cell connected to the first word line WL1, which is a selected word line, and the second bit line BL2, which is a non-selected bit line. In an example embodiment illustrated in FIG. 6A, the second memory cell MC2 may be an unprogrammed memory cell, and thus the second memory cell MC2 may have a threshold voltage in the first voltage range. For example, all non-selected memory cells connected to the first word line WL1 may have a threshold voltage in the first voltage range.

To execute a programming operation for the first memory cell MC1, the voltage controller of the memory device may input a first word line voltage to the first word line WL1 and may input a first bit line voltage to the third bit line BL3. The second memory cell MC2 may be connected to the first word line WL1, which is a selected word line, but since the second memory cell MC2 has a threshold voltage in the first voltage range, the second memory cell MC2 may not be turned on by the first word line voltage input to the first word line WL1. A method of controlling a voltage of each of the first word line WL1 and the third bit line BL3 to program the first memory cell MC1 will be described below with reference to FIG. 6B.

FIG. 6B is a view illustrating a voltage of the first word line WL1, which is a selected word line connected to the first memory cell MC1, and a voltage of the third bit line BL3, which is a selected bit line while executing a programming operation for the first memory cell MC1, which is a selected memory cell.

Referring to FIG. 6B, the voltage controller of the memory device may input a first word line voltage V_{WL1} to the first word line WL1, which is a selected word line, to execute the programming operation for the first memory cell MC1. For example, the first word line voltage V_{WL1} may be lower than a minimum voltage of the first voltage range to which the threshold voltage of the memory cell belongs in an unprogrammed state. In an example embodiment illustrated in FIG. 6A, the non-selected memory cells connected to the first word line WL1 are in the unprogrammed state, and may thus have a threshold voltage of the first voltage range, and even if the first word line voltage V_{WL1} is input to the first word line WL1, the non-selected memory cells may not be turned on. Accordingly, after the first word line voltage V_{WL1} is input to the first word line WL1, a word line voltage VWL may be maintained on a level equal to or similar to the first word line voltage V_{WL1}.

Then, the voltage controller may input a first bit line voltage V_{BL1} to the third bit line BL3, which is the selected bit line connected to the first memory cell MC1. The first memory cell MC1 may be turned on and a programming operation for the first memory cell MC1 may be executed by the program voltage determined by a voltage difference between the first word line voltage V_{WL1} input to the first word line WL1 and the first bit line voltage V_{BL1} input to the third bit line BL3. The program voltage input to the first memory cell MC1 may be higher than a maximum voltage of the first voltage range S1 described above with reference to FIG. 5.

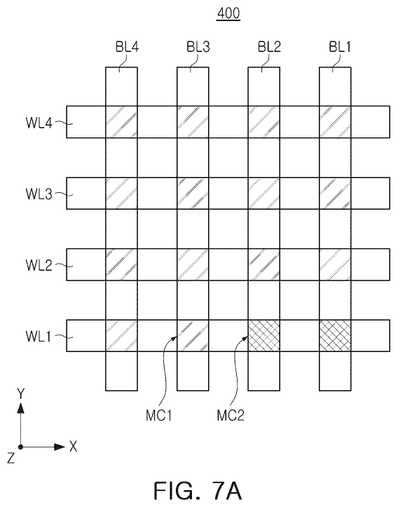

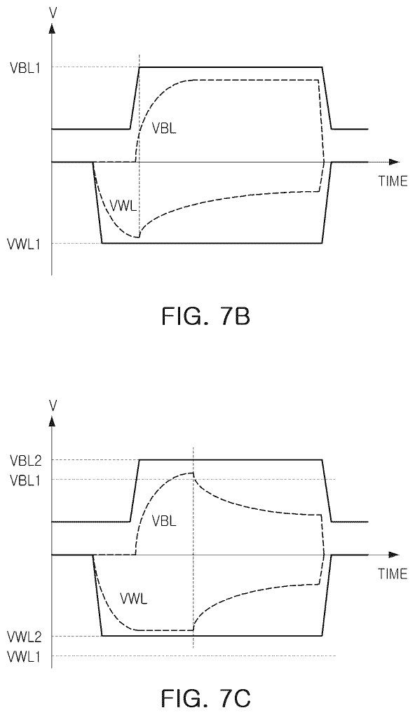

FIGS. 7A to 7C are views provided to illustrate a programming operation of a memory device according to an example embodiment of the present disclosure.

A cell array 400 according to an example embodiment illustrated in FIG. 7A may share the technical feature identical to or equivalent to the cell array 400 described in FIG. 6A above. Accordingly, descriptions overlapping the configuration described in FIG. 6A will be simplified or omitted.

In an example embodiment illustrated in FIG. 7A, the first memory cell MC1 may be a selected memory cell. Accordingly, the first word line WL1 connected to the first memory cell MC1 may be a selected word line, and the third bit line BL3 connected to the first memory cell MC1 may be a selected bit line. The first memory cell MC1 is an unprogrammed memory cell and may have a threshold voltage in the first voltage range as described above with reference to FIG. 5.

The second memory cell MC2 may be a non-selected memory cell connected to the first word line WL1, which is the selected word line, and the second bit line BL2, which is a non-selected bit line. In an example embodiment illustrated in FIG. 7A, the second memory cell MC2 may be a programmed memory cell, and thus, the second memory cell MC2 may have a threshold voltage of the second voltage range. As described above with reference to FIG. 5, the threshold voltage of the second voltage range may be lower than the threshold voltage of the first voltage range.

Since the second memory cell MC2 is connected to the first word line WL1, which is the selected word line, the second memory cell MC2 may be unintentionally turned on by the word line voltage input to the first word line WL1. For example, when the threshold voltage of the second memory cell MC2 is relatively significantly low, the second memory cell MC2 may be turned on only by the word line voltage input to the first word line WL1 to execute the programming operation for the first memory cell MC1.

As described above, when the second memory cell MC2 is turned on, a current may flow between the first word line WL1 and the second bit line BL2 through the second memory cell MC2, and the voltage of the first word line WL1 may change. Accordingly, even though the bit line voltage is input to the third bit line BL3 for programming the first memory cell MC1, a sufficient voltage for programming may not be applied to the first memory cell MC1, and the programming operation for the first memory cell MC1 may not be performed normally.

FIG. 7B may be a view illustrating the voltage of the selected word line WL1 and the voltage of the selected bit line BL3, in a programming operation for the first memory cell MC1, which is a selected memory cell, when the non-selected memory cell commonly connected to the selected word line is turned on.

Referring to FIG. 7B, the voltage controller of the memory device may input the first word line voltage V_{WL1} to the first word line WL1, which is the selected word line, to execute the programming operation for the first memory cell MC1. For example, when an absolute value of the first word line voltage V_{WL1} is higher than a minimum voltage of the second voltage range, the second memory cell MC2 which is in a program state, among the non-selected memory cells connected to the first word line WL1, may be unintentionally turned on. As the second memory cell MC2 is turned on, the current may flow through the first word line WL1 and the second bit line BL2, and thus, as illustrated in FIG. 7B, the absolute value of the word line voltage VWL may decrease.

After the first word line voltage V_{WL1} is input to the first word line WL1, the voltage controller may input the first bit line voltage V_{BL1} to the third bit line BL3, which is the selected bit line connected to the first memory cell MC1. The first memory cell MC1 may be programmed by a program voltage determined by the voltage difference between the first word line voltage V_{WL1} input to the first word line WL1 and the first bit line voltage V_{BL1} input to the third bit line BL3.

However, in an example embodiment illustrated in FIG. 7B, the second memory cell MC2 may be turned on to decrease an absolute value of the word line voltage VWL, and thus, even if the voltage controller inputs the first bit line voltage V_{BL1} to the third bit line BL3, a sufficient program voltage may not be input to the first memory cell MC1. Since sufficient program voltage is not input to the first memory cell MC1, the programming operation for the first memory cell MC1 may fail.

FIG. 7C may be a view illustrating the voltage of the selected word line WL1 and the voltage of the selected bit line BL3 to limit and/or prevent the non-selected memory cell commonly connected to the selected word line WL1 from being turned on, in a programming operation for the first memory cell MC1, which is a selected memory cell.

In an example embodiment illustrated in FIG. 7C, to limit and/or prevent the second memory cell MC2, which is a non-selected memory cell, from being turned on unintentionally, a second word line voltage V_{WL2}, higher than the first word line voltage V_{WL1}, may be input to the first word line WL1, which is a selected word line. An absolute value of the second word line voltage V_{WL2} may be less than an absolute value of the first word line voltage V_{WL1}, and an absolute value of the second word line voltage V_{WL2} may be less than a minimum voltage of the second voltage range. As the second word line voltage V_{WL2} is input to the first word line WL1, which is the selected word line, the second memory cell MC2 connected to the first word line WL1 may not be turned on. Accordingly, the word line voltage VWL input to the first word line WL1 may not decrease and may be maintained to be identical or similar to the second word line voltage VWL2.

When the voltage controller inputs a second word line voltage V_{WL2}, higher than the first word line voltage V_{WL1} to the first word line WL1, which is a selected word line, even if the voltage controller inputs the first bit line voltage V_{BL1} to the third bit line BL3, which is a selected bit line, a sufficient program voltage may not be input to the first memory cell MC1, which is the selected memory cell. To input sufficient program voltage to the first memory cell MC1, the voltage controller may input a second bit line voltage V_{BL2}, higher than the first bit line voltage V_{BL1}, to the third bit line BL3. By inputting the second word line voltage V_{WL2} to the first word line WL1 and the second bit line voltage V_{BL2} to the third bit line BL3, the first memory cell MC1 may receive sufficient program voltage and successfully execute a programming operation.

In an example embodiment of the present disclosure, to limit and/or prevent non-selected memory cells from being turned on unintentionally, the word line voltage input to the selected word line may be increased. In addition, to successfully execute the programming operation for the selected memory cell, the bit line voltage input to the selected bit line may be increased by the same magnitude as the increased word line voltage. Accordingly, the non-selected memory cell may be limited and/or prevented from being turned on and the success rate of the programming operation for the selected memory cell may be increased, thereby improving the performance of the memory device.

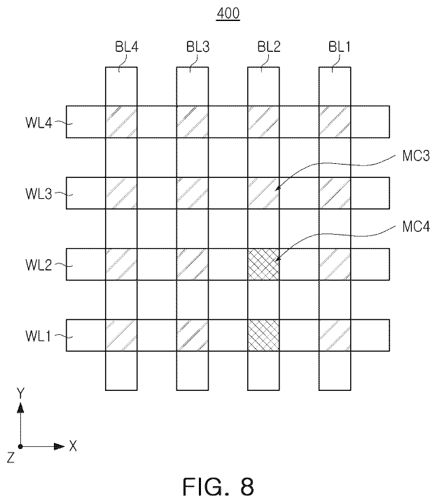

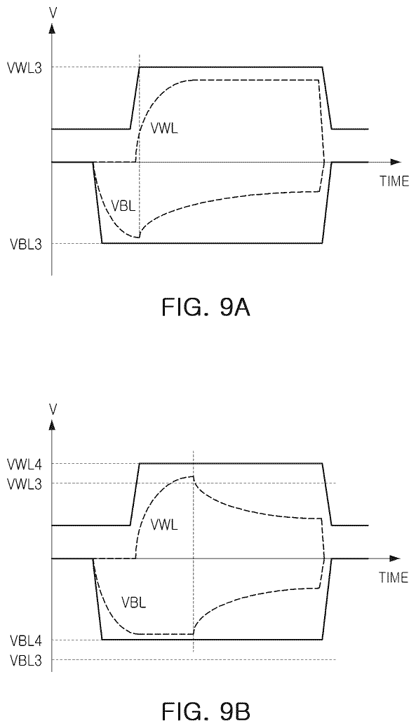

FIGS. 8, 9A, and 9B are views provided to illustrate a programming operation of the memory device according to an example embodiment of the present disclosure.

The cell array 400 according to an example embodiment illustrated in FIG. 8 may share technical feature identical to or equivalent to the cell array 400 described in FIG. 6A above. Accordingly, the description overlapping the configuration described in FIG. 6A will be briefly described or omitted.

In an example embodiment of the present disclosure, each of the plurality of memory cells may include a selector. For example, the selector may be an OTS element. The OTS element may be bidirectional, and may respond to both positive and negative voltages.

Due to the bidirectional operation of the OTS element, the memory cell may have a threshold voltage in a first voltage range and a threshold voltage in a second voltage range. For example, when a write operation is performed on the memory cell using a negative voltage and a read operation is performed on the memory cell using a positive voltage, the memory cell may have a threshold voltage in the first voltage range. When the write operation is performed on the memory cell using the positive voltage and the read operation is performed on the memory cell using the negative voltage, the memory cell may have a threshold voltage in the second voltage range. The first voltage range may be greater than the second voltage range.

Referring to FIG. 8, a plurality of memory cells may be connected to at least one of the first to fourth word lines WL1 to WL4, and may be connected to at least one of the first to fourth bit lines BL1 to BL4. For example, a lower surface of a third memory cell MC3 may be connected to a third word line WL3, and an upper surface of the third memory cell MC3 may be connected to a second bit line BL2. A lower surface of a fourth memory cell MC4 may be connected to a second word line WL2, and an upper surface of the fourth memory cell MC4 may be connected to a second bit line BL2.

In an example embodiment of the present disclosure, in a programming operation for a selected memory cell connected to a selected bit line among a plurality of bit lines, the voltage controller of a memory device may input the bit line voltage to the selected bit line, and may input the word line voltage to the selected word line connected to the selected memory cell to execute the programming operation. For example, the bit line voltage input to the selected bit line may be a negative voltage, and the word line voltage input to the selected word line may be a positive voltage.

In an example embodiment illustrated in FIG. 8, the third memory cell MC3 may be the selected memory cell. Accordingly, the second bit line BL2 connected to the third memory cell MC3 may be a selected bit line, and the third word line WL3 connected to the third memory cell MC3 may be a selected word line. The third memory cell MC3 may be an unprogrammed memory cell, and may have a threshold voltage in the first voltage range as described above with reference to FIG. 5.

The fourth memory cell MC4 may be a non-selected memory cell connected to the second bit line BL2, which is a selected bit line, and the second word line WL2, which is a non-selected word line. In an example embodiment illustrated in FIG. 8, the fourth memory cell MC4 may be a programmed memory cell, and thus, the fourth memory cell MC4 may have a threshold voltage of the second voltage range. As described above with reference to FIG. 5, a threshold voltage of the second voltage range may be lower than a threshold voltage of the first voltage range.

Since the fourth memory cell MC4 is connected to the second bit line BL2, which is the selected bit line, the fourth memory cell MC4 may be unintentionally turned on by the bit line voltage input to the second bit line BL2. For example, when the threshold voltage of the fourth memory cell MC4 is relatively significantly low, the fourth memory cell MC4 may be turned on only by the bit line voltage input to the second bit line BL2 to execute a programming operation for the third memory cell MC3.

As described above, when the fourth memory cell MC4 is turned on, a current may flow between the second bit line BL2 and the second word line WL2 through the fourth memory cell MC4, and the voltage of the second bit line BL2 may change. Accordingly, even though the word line voltage is input to the third word line WL3 to program the third memory cell MC3, a sufficient voltage for the program may not be applied to the third memory cell MC3, and the programming operation for the third memory cell MC3 may not be executed normally.

FIG. 9A may be a view illustrating voltages of the selected bit line BL2 and the selected word line WL3 when a non-selected memory cell commonly connected to a selected bit line is turned on, in a programming operation for the third memory cell MC3, which is a selected memory cell.

Referring to FIG. 9A, the voltage controller of the memory device may input a third bit line voltage V_{BL3} to the second bit line BL2, which is a selected bit line, to execute a programming operation for the third memory cell MC3. For example, when the absolute value of the third bit line voltage V_{BL3} is higher than a minimum voltage of the second voltage range, among the non-selected memory cells connected to the second bit line BL2, the fourth memory cell MC4, which is in a program state, may be unintentionally turned on. As the fourth memory cell MC4 is turned on, the current may flow through the second bit line BL2 and the second word line WL2, and thus, an absolute value of a bit line voltage VBL may decrease as illustrated in FIG. 9A.

After the third bit line voltage V_{BL3} is input to the second bit line BL2, the voltage controller may input a third word line voltage V_{WL3} to the third word line WL3, which is a selected word line connected to the third memory cell MC3. The third memory cell MC3 may be programmed by a program voltage determined by a voltage difference between the third bit line voltage V_{BL3} input to the second bit line BL2 and the third word line voltage V_{WL3} input to the third word line WL3.

However, in an example embodiment illustrated in FIG. 8, since the fourth memory cell MC4 is turned on to decrease an absolute value of the bit line voltage VBL, even if the voltage controller inputs the third word line voltage V_{WL3} to the third word line WL3, a sufficient program voltage may not be input to the third memory cell MC3. Since the third memory cell MC3 is not input with sufficient program voltage, the programming operation for the third memory cell MC3 may fail.

FIG. 9B may be a view illustrating a voltage of the selected bit line BL2 and a voltage of the selected word line WL3 to limit and/or prevent a non-selected memory cell commonly connected to the selected bit line BL2 from being turned on, in a programming operation for the third memory cell MC3, which is a selected memory cell.

In an example embodiment illustrated in FIG. 9B, to limit and/or prevent the fourth memory cell MC4, which is a non-selected memory cell, from being unintentionally turned on, a fourth bit line voltage V_{BL4} greater than the third bit line voltage V_{BL3} may be input to the second bit line BL2, which is a selected bit line. An absolute value of the fourth bit line voltage V_{BL4} may be less than an absolute value of the third bit line voltage V_{BL3}, and the absolute value of the fourth bit line voltage V_{BL4} may be less than a minimum voltage of the second voltage range. By inputting the fourth bit line voltage V_{BL4} to the second bit line BL2, which is the selected bit line, the fourth memory cell MC4 connected to the second bit line BL2 may not be turned on. Accordingly, the bit line voltage VBL input to the second bit line BL2 may not decrease and may be maintained to be identical to or similar to the fourth bit line voltage V_{BL4}.

When the voltage controller inputs the fourth bit line voltage V_{BL4}, greater than the third bit line voltage V_{BL3} to the second bit line BL2, which is the selected bit line, even if the voltage controller inputs the third word line voltage V_{WL3} to the third word line WL3, which is the selected word line, sufficient program voltage may not be input to the third memory cell MC3, which is the selected memory cell. To input sufficient program voltage to the third memory cell MC3, the voltage controller may input a fourth word line voltage V_{WL4}, greater than the third word line voltage V_{WL3}, to the third word line WL3. By inputting the fourth bit line voltage V_{BL4} to the second bit line BL2 and the fourth word line voltage V_{WL4} to the third word line WL3, the third memory cell MC3 may receive sufficient program voltage and successfully execute a programming operation.

In an example embodiment of the present disclosure, to limit and/or prevent a non-selected memory cell from being unintentionally turned on, a bit line voltage input to a selected bit line may be increased. In addition, to successfully execute a programming operation for a selected memory cell, the word line voltage input to the selected word line may be increased by the same magnitude as the increased bit line voltage. Accordingly, by limiting and/or preventing the non-selected memory cell from being turned on and increasing the success rate of the programming operation for the selected memory cell, the performance of a memory device may be improved.

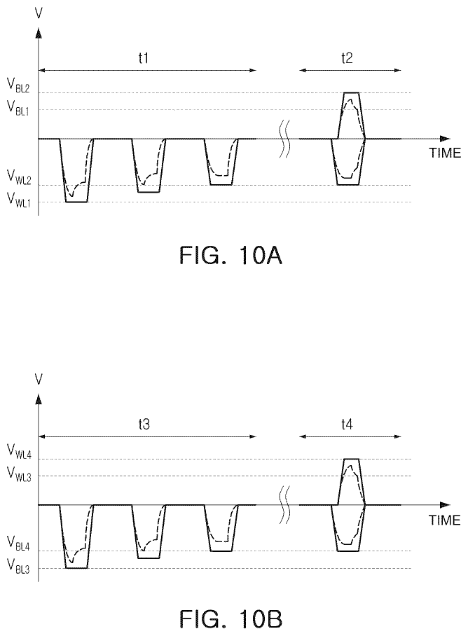

FIGS. 10A and 10B are views provided to illustrate a programming operation of a memory device according to an example embodiment of the present disclosure.

A memory device according to an example embodiment of the present disclosure may include a cell region and a peripheral circuit region. The cell region may include a plurality of memory cells disposed in regions in which a plurality of word lines and a plurality of bit lines intersect each other, and respectively including a selector. The peripheral circuit region may include a current monitoring circuit configured to monitor the current flowing through the plurality of word lines or the plurality of bit lines, and a voltage controller configured to input a voltage to each of the plurality of word lines and the plurality of bit lines.

First, referring to FIG. 10A, in a programming operation for a selected memory cell connected to a selected word line, among a plurality of word lines, the voltage controller may input a first word line voltage V_{WL1} to the selected word line. Depending on whether a non-selected memory cell connected to the selected word line is programmed, the non-selected memory cell may be unintentionally turned on by the first word line voltage V_{WL1} input to the selected word line. For example, when the non-selected memory cell is programmed and has a threshold voltage, lower than the first word line voltage V_{WL1}, the non-selected memory cell may be turned on as the first word line voltage V_{WL1} is input to the selected word line. When the non-selected memory cell is turned on by the first word line voltage V_{WL1}, the current may flow to the selected word line through the non-selected memory cell.

The current monitoring circuit may compare the current of the selected word line with the reference current. The current monitoring circuit may confirm whether at least one non-selected memory cell connected to the selected word line is turned on, by comparing the current of the selected word line with the reference current. For example, the reference current may be determined based on the minimum current flowing in the selected memory cell when the selected memory cell is turned on. When the non-selected memory cell is turned on, the current of the selected word line may be greater than the reference current, and when the non-selected memory cell is not turned on, the current of the selected word line may be less than the reference current.

When the current of the selected word line is greater than the reference current, the voltage controller may input a second word line voltage V_{WL2} greater than the first word line voltage V_{WL1} to the selected word line. By inputting the second word line voltage V_{WL2} in which an absolute value thereof is less than the first word line voltage V_{WL1} to the selected word line, the non-selected memory cell turned on by the first word line voltage V_{WL1} may be turned off. For example, a difference between the first word line voltage V_{WL1} and the second word line voltage V_{WL2} may be 0.01 V or more and 1 V or less.

The process may be performed one or more times until the current monitoring circuit determines that the current of the selected word line is less than the reference current. The process may be performed during a first time t1, and the process may be defined as a pre-programming operation. While the voltage controller gradually increases the voltage input to the selected word line from the first word line voltage V_{WL1}, the current monitoring circuit may compare the current of the selected word line with the reference current. Under the condition that the current of the selected word line is determined to be less than the reference current by the current monitoring circuit, the voltage input by the voltage controller to the selected word line may be determined as the second word line voltage V_{WL2}.

When the current of the selected word line is determined to be less than the reference current, to execute a programming operation for the selected memory cell, the voltage controller may input the first bit line voltage V_{BL1} or the second bit line voltage V_{BL2} greater than the first bit line voltage V_{BL1} to the selected bit line connected to the selected memory cell. The program voltage may be determined by a difference between the first word line voltage V_{WL1} and the first bit line voltage V_{BL1}. When the current of the selected word line is determined to be less than the reference current under the condition that the first word line voltage V_{WL1} is input to the selected word line, the voltage controller may execute the programming operation for the selected memory cell by inputting the first bit line voltage V_{BL1} to the selected bit line.

Meanwhile, when the current of the selected word line is determined to be less than the reference current under the condition that the second word line voltage V_{WL2} greater than the first word line voltage V_{WL1} is input to the selected word line, the voltage controller may input the second bit line voltage V_{BL2} greater than the first bit line voltage V_{BL1} to the selected bit line. Considering that the second word line voltage V_{WL2} greater than the first word line voltage V_{WL1} is input to the selected word line, the voltage controller may input the second bit line voltage V_{BL2} greater than the first bit line voltage V_{BL1} to the selected bit line, so that a program voltage having a sufficiently high magnitude may be applied to the selected memory cell. The process may be performed at least once during a second time t2, and the process may be defined as a programming operation.

The word line voltage input to the selected word line and the bit line voltage input to the selected bit line may have different polarities. For example, the first word line voltage V_{WL1} and the second word line voltage V_{WL2} may be negative voltages, and the first bit line voltage V_{BL1} and the second bit line voltage V_{BL2} may be positive voltages. A difference between the first word line voltage V_{WL1} and the second word line voltage V_{WL2} may be the same as a difference between the first bit line voltage V_{BL1} and the second bit line voltage V_{BL2}. The voltage controller may compensate for the bit line voltage input to the selected bit line based on the magnitude compensated for the word line voltage input to the selected word line. The difference between the first word line voltage V_{WL1} and the first bit line voltage V_{BL1} may be the same as the difference between the second word line voltage V_{WL2} and the second bit line voltage V_{BL2}.

In an example embodiment of the present disclosure, by compensating the voltage input to the selected bit line and the selected word line, at least one non-selected memory cell connected to the selected word line may be limited and/or prevented from being turned on in the programming operation for the selected memory cell, and the programming operation for the selected memory cell may be made successful. Therefore, the performance of the memory device may be improved.

FIG. 10B may be a view illustrating a programming operation for a selected memory cell connected to a selected bit line among a plurality of bit lines.

Referring to FIG. 10B, the voltage controller may input a third bit line voltage V_{BL3} to the selected bit line. Depending on whether or not a non-selected memory cell connected to the selected bit line is programmed, the non-selected memory cell may be unintentionally turned on by the third bit line voltage V_{BL3} input to the selected bit line. For example, when the non-selected memory cell is programmed and has a threshold voltage lower than a third bit line voltage V_{BL3}, the non-selected memory cell may be turned on as the third bit line voltage V_{BL3} is input to the selected bit line. When the non-selected memory cell is turned on by the third bit line voltage V_{BL3}, the current may flow to the selected bit line through the non-selected memory cell.

The current monitoring circuit may compare the current of the selected bit line with the reference current. By comparing the current of the selected bit line with the reference current, the current monitoring circuit may confirm whether at least one non-selected memory cell connected to the selected bit line is turned on. For example, the reference current may be determined based on the minimum current flowing in the selected memory cell when the selected memory cell is in a turned-on state. When the non-selected memory cell is turned on, the current of the selected bit line may be greater than the reference current, and when the non-selected memory cell is not turned on, the current of the selected bit line may be less than the reference current.

When the current of the selected bit line is greater than the reference current, the voltage controller may input a fourth bit line voltage V_{BL4} higher than the third bit line voltage V_{BL3} to the selected bit line. By inputting the fourth bit line voltage V_{BL4} lower in absolute value than the third bit line voltage V_{BL3} to the selected bit line, the non-selected memory cell turned on by the third bit line voltage V_{BL3} may be turned off. For example, a difference between the third bit line voltage V_{BL3} and the fourth bit line voltage V_{BL4} may be 0.01 V or more and 1 V or less.

The process may be performed one or more times until the current monitoring circuit determines that the current of the selected bit line is less than the reference current. The process may be performed during a third time t3, and the process may be defined as a pre-programming operation. While the voltage controller gradually increases a voltage input to the selected bit line from the third bit line voltage V_{BL3}, the current monitoring circuit may compare the current of the selected bit line with the reference current. Under the condition that the current of the selected bit line is determined to be less than the reference current by the current monitoring circuit, the voltage input to the selected bit line by the voltage controller may be determined as the fourth bit line voltage V_{BL4}.

When the current of the selected bit line is determined to be less than the reference current, to execute a programming operation for the selected memory cell, the voltage controller may input the third word line voltage V_{WL3} or the fourth word line voltage V_{WL4} greater than the third word line voltage V_{WL3} to the selected word line connected to the selected memory cell. The program voltage may be determined by the difference between the third bit line voltage V_{BL3} and the third word line voltage V_{WL3}. When the current of the selected bit line is determined to be less than the reference current under the condition that the third bit line voltage V_{BL3} is input to the selected bit line, the voltage controller may execute the programming operation for the selected memory cell by inputting the third word line voltage V_{WL3} to the selected word line.

On the other hand, when the current of the selected bit line is determined to be less than the reference current under the condition that the fourth bit line voltage V_{BL4} greater than the third bit line voltage V_{BL3} is input to the selected bit line, the voltage controller may input the fourth word line voltage V_{WL4} higher than the third word line voltage V_{WL3} to the selected word line. Considering that the fourth bit line voltage V_{BL4} higher than the third bit line voltage V_{BL3} is input to the selected bit line, the voltage controller may input the fourth word line voltage V_{WL4} higher than the third word line voltage V_{WL3} to the selected word line, so that a program voltage having a sufficiently high magnitude may be applied to the selected memory cell. The process may be performed at least once during a fourth time t4, and the process may be defined as a programming operation.

The word line voltage input to the selected word line and the bit line voltage input to the selected bit line may have different polarities. For example, the third bit line voltage V_{BL3} and the fourth bit line voltage V_{BL4} may be negative voltages, and the third word line voltage V_{WL3} and the fourth word line voltage V_{WL4} may be positive voltages. A difference between the third bit line voltage V_{BL3} and the fourth bit line voltage V_{BL4} may be the same as a difference between the third word line voltage V_{WL3} and the fourth word line voltage V_{WL4}. The voltage controller may compensate for the word line voltage input to the selected word line based on the magnitude compensated for the word line voltage input to the selected word line. The difference between the third bit line voltage V_{BL3} and the fourth bit line voltage V_{BL4} may be the same as the difference between the third word line voltage V_{WL3} and the fourth word line voltage V_{WL4}.

In an example embodiment of the present disclosure, the voltage controller may compensate for the voltage input to the selected bit line and the selected word line, so that at least one non-selected memory cell connected to the selected bit line may be limited and/or prevented from being turned on in the programming operation for the selected memory cell, and the programming operation for the selected memory cell may be made successful. Therefore, the performance of the memory device may be improved.

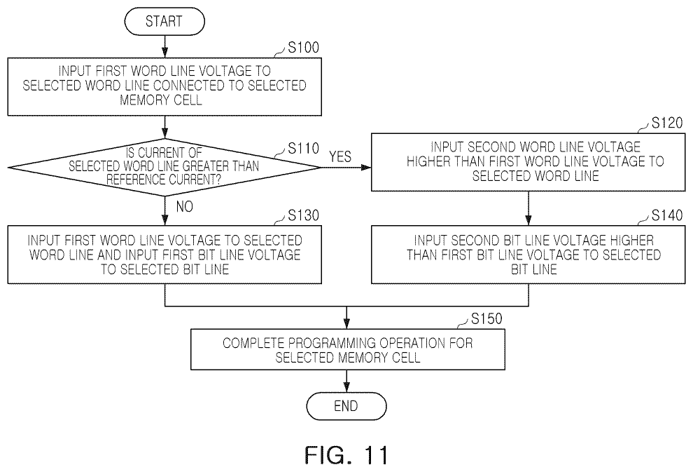

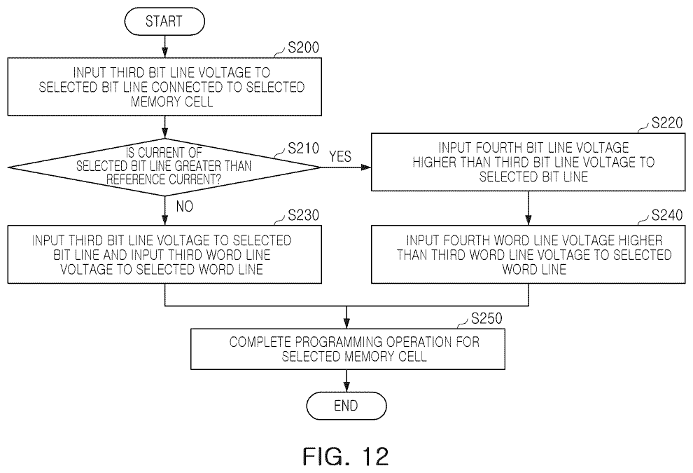

FIGS. 11 and 12 are flowcharts provided to illustrate a programming operation of a memory device according to an example embodiment of the present disclosure.

FIG. 11 may be a view illustrating a programming operation performed on a selected memory cell in a memory device according to an example embodiment of the present disclosure. The programming operation according to an example embodiment of the present disclosure may start by inputting a first word line voltage to a selected word line connected to a selected memory cell by a voltage controller of a peripheral circuit region (S100). For example, the first word line voltage may be a negative voltage.

A current monitoring circuit in the peripheral circuit region may monitor whether the current of the selected word line is greater than a reference current (S110). For example, a selected memory cell to be programmed may have a threshold voltage of a first voltage range. Each of the non-selected memory cells connected to the selected word line may have a threshold voltage of the first voltage range, or a threshold voltage of a second voltage range lower than the first voltage range. For example, at least one programmed non-selected memory cell among the non-selected memory cells may have a threshold voltage of the second voltage range.

For example, in operation S100, an absolute value of the first word line voltage input to the selected word line may be greater than a threshold voltage of at least one programmed non-selected memory cell. In this case, the non-selected memory cell may be unintentionally turned on by the first word line voltage input to the selected word line.

When at least one non-selected memory cell connected to the selected word line is turned on, as a current path is formed through the turned-on non-selected memory cell, the current of the selected word line may be greater than the reference current. On the other hand, when all of the non-selected memory cells connected to the selected word line are not turned on but turned off, the current of the selected word line may be less than the reference current. Accordingly, the current monitoring circuit may monitor whether the non-selected memory cell is turned on by comparing the current of the selected word line with the reference current.

When it is determined in operation S110 that the current of the selected word line is greater than the reference current, the voltage controller may input a second word line voltage higher than the first word line voltage to the selected word line (S120). The second word line voltage may be a negative voltage, such as the first word line voltage, and may have an absolute value lower than the first word line voltage.

By inputting the second word line voltage lower than the first word line voltage to the selected word line, the non-selected memory cell that is turned on may be turned off. For example, an absolute value of the second word line voltage may be less than a minimum voltage of the second voltage range to which the threshold voltage of the programmed non-selected memory cell belongs. Accordingly, the voltage controller may input the second word line voltage to the selected word line, so that the non-selected memory cell turned on by the first word line voltage input in operation S100 may be turned off.

When it is determined in operation S110 that the current of the selected word line is less than the reference current, the first word line voltage may be input to the selected word line, and the first bit line voltage may be input to the selected bit line (S130). A program voltage may be determined by a difference between the first word line voltage and the first bit line voltage. As the first word line voltage is input to the selected word line, and the first bit line voltage is input to the selected bit line, a programming operation for the selected memory cell may be executed.

When the current of the selected word line is less than the reference current and the second word line voltage is input to the selected word line, to input a sufficient program voltage to the selected memory cell, the voltage controller may input a second bit line voltage higher than the first bit line voltage to the selected bit line (S140). In an example embodiment, a difference between the first word line voltage and the second word line voltage may be the same as a difference between the first bit line voltage and the second bit line voltage. Alternatively, the difference between the first bit line voltage and the second bit line voltage may be greater than the difference between the first word line voltage and the second word line voltage. The voltage controller may compensate for the word line voltage input to the selected word line so as to turn off at least one non-selected memory cell that is turned on by the first word line voltage, among the non-selected memory cells connected to the selected word line. In addition, the voltage controller may also compensate for the bit line voltage input to the selected bit line as much as the word line voltage is compensated, so that a programming operation for the selected memory cell may be executed.

Next, the programming operation for the selected memory cell may be completed (S150). The programming operation for the selected memory cell may be executed by a program voltage determined by a difference between the first word line voltage and the first bit line voltage, or the program voltage determined by a difference between the second word line voltage and the second bit line voltage.

A memory device according to an example embodiment of the present disclosure may provide a memory device having improved performance, which may limit and/or prevent at least one non-selected memory cell connected to the selected word line from being turned on and may execute the programming operation for the selected memory cell, by compensating for the word line voltage input to the selected word line and the bit line voltage input to the selected bit line.

FIG. 12 may be a view illustrating a programming operation executed for a selected memory cell in a memory device according to an example embodiment of the present disclosure. The programming operation according to an example embodiment of the present disclosure may start by inputting a third bit line voltage to a selected bit line connected to the selected memory cell by a voltage controller of a peripheral circuit region (S200). For example, the third bit line voltage may be a negative voltage.

A current monitoring circuit of the peripheral circuit region may monitor whether the current of the selected bit line is greater than the reference current (S210). For example, the selected memory cell to be programmed may have a threshold voltage of a first voltage range. Each of the non-selected memory cells connected to the selected bit line may have a threshold voltage of the first voltage range, or a threshold voltage of a second voltage range lower than the first voltage range. For example, at least one programmed non-selected memory cell among the non-selected memory cells may have a threshold voltage of the second voltage range.

For example, an absolute value of the third bit line voltage input to the selected bit line in operation S200 may be greater than a threshold voltage of at least one programmed non-selected memory cell. In this case, the non-selected memory cell may be unintentionally turned on by the third bit line voltage input to the selected bit line.

When at least one non-selected memory cell connected to the selected bit line is turned on, the current of the selected bit line may be greater than the reference current as a current path is formed through the turned-on non-selected memory cell. On the other hand, when all of the non-selected memory cells connected to the selected bit line are not turned on but turned off, the current of the selected bit line may be less than the reference current. Accordingly, the current monitoring circuit may monitor whether the non-selected memory cell is turned on by comparing the current of the selected bit line with the reference current.

When it is determined in operation S210 that the current of the selected bit line is greater than the reference current, the voltage controller may input a fourth bit line voltage higher than the third bit line voltage to the selected bit line (S220). The fourth bit line voltage may be a negative voltage equal to the third bit line voltage and may have an absolute value less than the third bit line voltage.

By inputting the fourth bit line voltage whose absolute value is less than the third bit line voltage to the selected bit line, the turned-on non-selected memory cell may be turned off. For example, the absolute value of the fourth bit line voltage may be less than a minimum voltage of the second voltage range to which the threshold voltage of the programmed non-selected memory cell belongs. Accordingly, the voltage controller may input the third bit line voltage to the selected bit line, so that the non-selected memory cell turned on by the third bit line voltage input in operation S200 may be turned off.

When it is determined in operation S210 that the current of the selected bit line is less than the reference current, the third bit line voltage may be input to the selected bit line, and the third word line voltage may be input to the selected word line (S230). A program voltage may be determined by a difference between the third bit line voltage and the third word line voltage. As the third bit line voltage is input to the selected bit line, and the third word line voltage is input to the selected word line, a programming operation for the selected memory cell may be executed.

When the current of the selected bit line is less than the reference current, and the fourth bit line voltage is input to the selected bit line, to input sufficient program voltage to the selected memory cell, the voltage controller may input the fourth word line voltage higher than the third word line voltage, to the selected word line (S240). In an example embodiment, a difference between the third bit line voltage and the fourth bit line voltage may be equal to a difference between the third word line voltage and the fourth word line voltage. Alternatively, the difference between the third word line voltage and the fourth word line voltage may be greater than the difference between the third bit line voltage and the fourth bit line voltage. The voltage controller may compensate for the bit line voltage input to the selected bit line so as to turn off at least one non-selected memory cell turned on by the third bit line voltage, among the non-selected memory cells connected to the selected bit line. In addition, the voltage controller may compensate for the word line voltage input to the selected word line as much as the bit line voltage is compensated, so that a programming operation for the selected memory cell may be executed.

Next, the programming operation for the selected memory cell may be completed (S250). The programming operation for the selected memory cell may be executed by a program voltage determined by a difference between the third bit line voltage and the third word line voltage, or a program voltage determined by a difference between the fourth bit line voltage and the fourth word line voltage.

A memory device according to an example embodiment of the present disclosure may provide a memory device having improved performance, which may limit and/or prevent at least one non-selected memory cell connected to the selected bit line from being turned on and may execute the programming operation for the selected memory cell, by compensating for the bit line voltage input to the selected bit line and the word line voltage input to the selected word line.

In an example embodiment, a memory device, may include a cell region including a plurality of memory cells in regions where a plurality of word lines and a plurality of bit lines intersect each other, the plurality of memory cells each respectively may include a selector such that the plurality of memory cells respectively may include a plurality of selectors; and a peripheral circuit region including a current monitoring circuit and a voltage controller, the current monitoring circuit being configured to monitor a current flowing through the plurality of word lines, and the voltage controller being configured to input a voltage to each of the plurality of word lines and the plurality of bit lines. In a programming operation for a selected memory cell connected to a selected word line among the plurality of word lines and a selected bit line among the plurality of bit lines, the current monitoring circuit may be configured to compare a current of a selected word line with a reference current, the voltage controller may be configured to input a first word line voltage to the selected word line and a first bit line voltage to a selected bit line in response to detecting the current of the selected word line is not greater than the reference current, and the voltage controller may be configured to input a second word line voltage to the selected word line and a second bit line voltage to the selected bit line in response to detecting the current of the selected word line is greater than the reference current. The selected memory cell may be among the plurality of memory cells. The second word line voltage may be higher than the first word line voltage, and the second bit line voltage may be higher than the first word line voltage.

A difference between the first word line voltage and the second word line voltage may be equal to a difference between the first bit line voltage and the second bit line voltage.

A difference between the first word line voltage and the first bit line voltage may be equal to a difference between the second word line voltage and the second bit line voltage.

The reference current may be determined based on a minimum current flowing in the selected memory cell when the selected memory cell is turned on.

The first word line voltage and the second word line voltage may be negative voltages, and the first bit line voltage and the second bit line voltage may be positive voltages.

A method of programing a memory device according to an example embodiment may be provided, where the memory device may include a plurality of memory cells disposed in regions in which a plurality of word lines and a plurality of bit lines may intersect each other, and the plurality of memory cells respectively each may include a selector. The method may include detecting a current of a selected word line, comparing the current of the selected word line with a reference current, and (i) inputting a first word line voltage to the selected word line and a first bit line voltage to a selected bit line in response to detecting the current of the selected word line is not greater than the reference current, or (ii) inputting a second word line voltage to the selected word line and a second bit line voltage to the selected bit line in response to detecting the current of the selected word line is greater than the reference current. The selected memory cell may be among the plurality of memory cells. The selected word line may be among the plurality of word lines. The selected bit line may be among the plurality of bit lines. The second word line voltage may be higher than the first word line voltage, and the second bit line voltage may be higher than the first word line voltage.

An absolute value of the second word line voltage may be less than an absolute value of the first word line voltage.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A memory device, comprising:
a cell region including a plurality of memory cells in regions where a plurality of word lines and a plurality of bit lines intersect each other, the plurality of memory cells each respectively including a selector such that the plurality of memory cells respectively include a plurality of selectors; and
a peripheral circuit region including a current monitoring circuit and a voltage controller, the current monitoring circuit being configured to monitor a current flowing through the plurality of word lines, and the voltage controller being configured to input a voltage to each of the plurality of word lines and the plurality of bit lines, wherein in a programming operation for a selected memory cell connected to a selected word line among the plurality of word lines and a selected bit line among the plurality of bit lines,
the voltage controller is configured to input a first word line voltage to the selected word line,
the current monitoring circuit is configured to compare a current of the selected word line with a reference current,
the voltage controller is configured to input a second word line voltage to the selected word line when the current of the selected word line is greater than the reference current,
the voltage controller is configured to input a first bit line voltage or a second bit line voltage to the selected bit line when the current of the selected word line is less than the reference current,
the second word line voltage is higher than the first word line voltage, and
the second bit line voltage is higher than the first word line voltage.

2. The memory device of claim 1, wherein a threshold voltage of each of the plurality of memory cells is determined by a magnitude of resistance of the selector.

3. The memory device of claim 1, wherein a difference between the first word line voltage and the second word line voltage is equal to a difference between the first bit line voltage and the second bit line voltage.

4. The memory device of claim 1, wherein a difference between the first word line voltage and the first bit line voltage is equal to a difference between the second word line voltage and the second bit line voltage.

5. The memory device of claim 1, wherein the reference current is determined based on a minimum current flowing in the selected memory cell when the selected memory cell is turned on.

6. The memory device of claim 1, wherein
the first word line voltage and the second word line voltage are negative voltages, and the first bit line voltage and the second bit line voltage are positive voltages.

7. The memory device of claim 1, wherein a difference between the first word line voltage and the second word line voltage is 0.01 V or more and 1 V or less.

8. The memory device of claim 1, wherein
the plurality of memory cells include a first memory cell, and
the first memory cell is configured to have a first state before the programming operation is executed and a second state after the programming operation is executed,
a threshold voltage of the first memory cell in the first state is a first voltage range, and the threshold voltage of the first memory cell in the second state is a second voltage range.

9. The memory device of claim 8, wherein the first voltage range is greater than the second voltage range.

10. The memory device of claim 1, wherein the memory device is connected to an external host through a Compute Express Link (CXL) interface.

11. The memory device of claim 1, wherein
the voltage controller is configured to inputs the second bit line voltage to the selected bit line when the current of the selected word line is less than the reference current and the second word line voltage is input to the selected word line.

12. The memory device of claim 1, wherein in the programming operation for the selected memory cell, which is connected to a selected bit line among the plurality of bit lines, the voltage controller is configured to input a third bit line voltage to the selected bit line,
the current monitoring circuit is configured to compare the current of the selected bit line with the reference current, and
the voltage controller is configured to input a fourth bit line voltage to the selected bit line when the current of the selected bit line is greater than the reference current and the voltage controller is configured inputs a fourth word line voltage to the selected word line when the current of the selected bit line is less than the reference current,
the fourth bit line voltage is higher than the third bit line voltage,
the fourth word line voltage is equal to or greater than a third word line voltage, and
the selected word line is connected to the selected memory cell.

13. The memory device of claim 12, wherein a difference between the third bit line voltage and the fourth bit line voltage is equal to a difference between the third word line voltage and the fourth word line voltage.

14. The memory device of claim 12, wherein
the third word line voltage and the fourth word line voltage are positive voltages, and
the third bit line voltage and the fourth bit line voltage are negative voltages.

15. The memory device of claim 12, wherein a difference between the third bit line voltage and the fourth bit line voltage is 0.01 V or more and 1 V or less.

16. A method of programing a memory device including a plurality of memory cells disposed in regions in which a plurality of word lines and a plurality of bit lines intersect each other, and the plurality of memory cells respectively each including a selector, the method comprising:
inputting a first word line voltage to a selected word line in a programming operation for a selected memory cell connected to the selected word line, the selected word line being among the plurality of word lines;
comparing a current of the selected word line with a reference current;
inputting a second word line voltage to the selected word line when a current of the selected word line is greater than the reference current, the second word line voltage being higher than the first word line voltage; and
inputting a first bit line voltage or a second bit line voltage to a selected bit line connected to the selected memory cell when the current of the selected word line is less than the reference current, the second bit line voltage being higher than the first bit line voltage, and the selected bit line being among the plurality of bit lines.

17. The method of programing a memory device of claim 16, wherein the inputting the second word line voltage to the selected word line is performed at least once.

18. The method of programing a memory device of claim 16, wherein the inputting the first bit line voltage or the second bit line voltage to the selected bit line is performed once.

19. The method of programing a memory device of claim 16, wherein
the second word line voltage is input to the selected word line during a first time,
the second bit line voltage is input to the selected bit line during a second time after the first time, and
the first time is longer than the second time.

20. A memory system, comprising:
a host using a Compute Express Link (CXL) interface; and
a memory device including a plurality of memory cells connected to the host, the plurality of memory cells being disposed in regions in which a plurality of word lines and a plurality of bit lines intersect each other, and the plurality of memory cells respectively each including a selector,
wherein the memory device includes a voltage controller configured to input voltages to the plurality of word lines and the plurality of bit lines,
in a programming operation for a selected memory cell connected to a selected word line among the plurality of word lines and a selected bit line among the plurality of bit lines, the voltage controller is configured to input a word line voltage to the selected word line, and
the voltage controller is configured to provide a compensated word line voltage by compensating for the word line voltage that is input to the selected word line until a current of the selected word line is lower than a reference current during a first time and the voltage controller is configured to compensate for a bit line voltage input to the selected bit line based on the compensated word line voltage during a second time after the first time.
